(19) United States
(12) Patent Application Publication
(10) Pub. No.: US 2024/0332432 A1
(43) Pub. Date: Oct. 3, 2024

(54) VARACTOR COMPRISING HIGH PERFORMANCE THIN FILM TRANSISTOR MATERIAL

(71) Applicant: Intel Corporation, Santa Clara, CA (US)

(72) Inventors: Sukru Yemenicioglu, Portland, OR (US); Abhishek Anil Sharma, Portland, OR (US); Sudipto Naskar, Portland, OR (US); Kalyan C. Kolluru, Portland, OR (US)

(73) Assignee: Intel Corporation, Santa Clara, CA (US)

(21) Appl. No.: 18/194,303

(22) Filed: Mar. 31, 2023

(51) Int. Cl. H01L 29/93; H01L 29/417; H01L 29/66

(52) U.S. Cl. CPC H01L 29/93; H01L 29/417; H01L 29/66022; H01L 29/66196; H01L 29/66969; H01L 29/2003; H01L 29/24

(57) ABSTRACT

An integrated circuit device comprising a varactor comprising a first conductive contact; a second conductive contact; and a thin film transistor (TFT) channel material coupled between the first conductive contact and the second conductive contact.

### BACKGROUND

A varactor is an electronic component that has a variable capacitance. The capacitance of a varactor may be adjusted through changing a voltage applied to the varactor. Varactors may be used in an integrated circuit device for various purposes, such as to facilitate wireless communication.

In some semiconductor processes, such as those where the transistor technology relies on gate-all-around devices or variants thereof, varactor fabrication becomes very challenging. A first type of varactor may utilize the reverse bias depletion region of a confined p-n junction. However, in some processes, fabricating p-n junctions reliably and with high control requires additional costly steps early in the process flow. Another type of varactor may utilize the capacitance between a gate and a channel of a transistor. However, currently available transistors generally do not provide a high enough controlled capacitance relative to parasitic capacitance to generate high quality factor varactors. Currently available transistors may also be susceptible to maximum voltage limitations due to breakdown concerns.

### BRIEF DESCRIPTION OF THE DRAWINGS

FIGS. 1A-1B illustrate a varactor in which HP TFT material is substantially orthogonal to an anode and cathode, in accordance with any of the embodiments disclosed herein.

FIG. 2 illustrate phases of manufacture of the varactor of FIGS. 1A-1B, in accordance with any of the embodiments disclosed herein.

FIG. 3 illustrates a varactor in which HP TFT material is vertically stacked between an anode and cathode, in accordance with any of the embodiments disclosed herein.

FIG. 4 illustrates varactors in which HP TFT material is formed between an anode and cathode in a horizontal grating configuration, in accordance with any of the embodiments disclosed herein.

FIG. 5 illustrates phases of manufacture of varactors in a horizontal grating configuration, in accordance with any of the embodiments disclosed herein.

FIG. 6 illustrates the varactors formed by the process of FIG. 5 with modulated depletion regions, in accordance with any of the embodiments disclosed herein.

FIG. 7 illustrates a method for forming a varactor, in accordance with any of the embodiments disclosed herein.

FIG. 8 illustrates a schematic of a cross-sectional view of an example integrated circuit device, in accordance with any of the embodiments disclosed herein.

FIG. 9 is a top view of a wafer and dies that may be included in a microelectronic assembly, in accordance with any of the embodiments disclosed herein.

FIG. 10 is a cross-sectional side view of an integrated circuit device that may be included in a microelectronic assembly, in accordance with any of the embodiments disclosed herein.

FIGS. 11A-11D are perspective views of example planar, FinFET, gate-all-around, and stacked gate-all-around transistors.

FIG. 12 is a cross-sectional side view of an integrated circuit device assembly that may include a microelectronic assembly, in accordance with any of the embodiments disclosed herein.

FIG. 13 is a block diagram of an example electrical device that may include a microelectronic assembly, in accordance with any of the embodiments disclosed herein.

### DETAILED DESCRIPTION

In various embodiments of the present disclosure, a varactor is formed using a high-performance thin film transistor (HP TFT) material coupled to an anode and cathode. Use of this HP TFT material may result in easier manufacturing of a varactor and/or improved varactor performance. For example, the HP TFT material may be deposited on any of a variety of dielectric materials (and does not have to be deposited on or formed of the substrate that is used as channel material for transistors on the front side, e.g., in the front-end-of-line (FEOL) portion of the integrated circuit). Accordingly, the location of the varactor is more flexible, and the varactor may even be placed on the back side of a wafer (e.g., opposite the side of the wafer comprising the FEOL and back-end-of-line (BEOL) components).

Embodiments of a varactor with HP TFT material may exhibit various performance improvements, such as one or more of the following. For example, a varactor may have a relatively low minimum capacitance (Cₘᵢₙ), because of decreased parasitic capacitance relative to a traditional varactor implemented using a transistor device with a floating gate or differential gate and a connected source and drain. The parasitic capacitance may also be improved since forming the varactor on the back side of the wafer may avoid various contact requirements on the front side. Relatedly, the varactor may have an improved maximum capacitance to minimum capacitance ratio. As another example, the varactor may also have an improved Q factor relative to standard semiconductor varactors. As yet another example, the varactor may exhibit a flatband voltage pushout.

Forming the varactor on the backside of a wafer may also conserve valuable space on the front side of the wafer (e.g., for FEOL devices, such as gate-all-around devices). In some embodiments, a varactor may be coupled to an inductor (e.g., to form an LC circuit) that is also on the back side of the wafer. Such embodiments may significantly reduce series resistance that would otherwise be present in such circuits where the inductor is formed on the back side of the wafer, but the varactor is formed on the front side. Although the varactor may be formed on the back side, the embodiments herein are not limited to such. For example, varactors with HP TFT material may additionally or alternatively be formed on the front side of the wafer (e.g., on the FEOL or BEOL).

Using an HP TFT material to form a varactor independent of a crystalline substrate (e.g., silicon substrate) may also provide flexibility in the process to tailor the structure according to the desired characteristics of the varactor.

In various embodiments, the varactor is an inversion mode varactor in which the capacitance of the varactor decreases as the voltage applied to the device is increased.

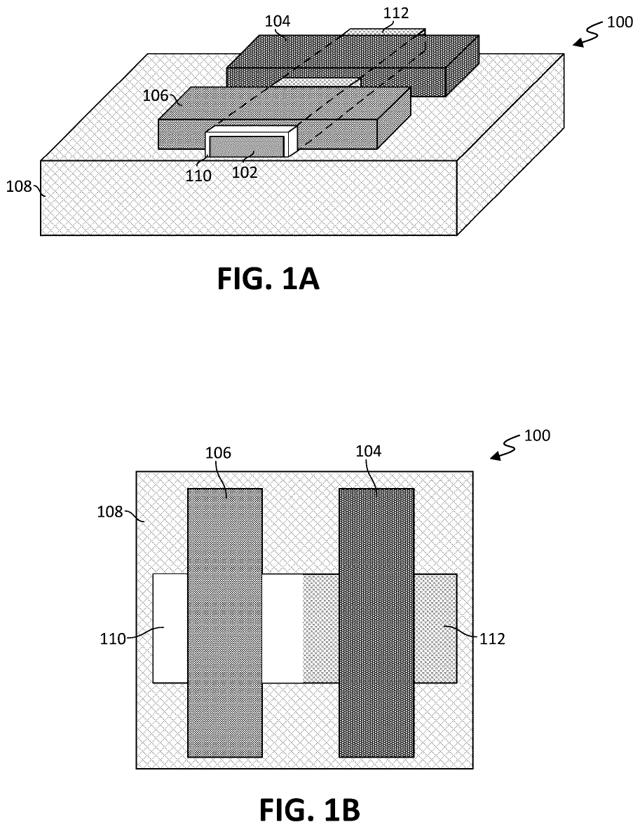

FIGS. 1A-1B illustrate a varactor 100 in which HP TFT material 102 is substantially orthogonal to an anode 104 and cathode 106, in accordance with any of the embodiments disclosed herein. FIG. 1A is a perspective view and FIG. 1B is a top view of the varactor 100.

Varactor 100 includes two conductive contacts (e.g., anode 104 and cathode 106) formed on a substrate 108 (which in some embodiments may be a non-crystalline substrate). HP TFT material 102 runs through the width of both the anode 104 and the cathode 106. In the embodiment depicted, the HP TFT material 102, the anode 104, and the cathode are each formed over the substrate 108. The portion of the HP TFT material 102 that passes through one of the conductive contacts (e.g., the cathode 106) is coated with a dielectric material 110 (e.g., an oxide) such that the HP TFT material does not contact the conductive contact 106. The portion of the HP TFT material 102 that passes through the other conductive contact (e.g., anode 104) may be coated with an ohmic contact material 112 (e.g., a material having a low resistance and/or free charge carriers to improve electrical conductivity between the anode 104 and the HP TFT material 102) such that the HP TFT material 102 is in indirect contact with this conductive contact. In other embodiments, the HP TFT material 102 may directly contact the conductive contact (e.g., anode 104) and the ohmic contact material 112 may be omitted (e.g., if the resistance between the anode 104 and the HP TFT material is suitable low). Thus, in various embodiments, the anode 104 and the HP TFT material 102 may form an ohmic contact (e.g., a junction between two conductors that has a linear current-voltage curve). The ohmic contact material 112 may comprise any suitable material to facilitate the ohmic contact, such as a degenerate semiconductor, such as doped polysilicon or other doped semiconductor with free available charge carriers.

The cathode 106 and the dielectric material 110 may operate in a somewhat similar fashion to a transistor gate while the HP TFT material 102 may operate somewhat similarly to a transistor channel. The accumulation of charge at the interface between the cathode 106 and the HP TFT material 102 may be modulated by varying a voltage applied between the anode 104 and cathode 106. This modulation in turn may change the capacitance (as measured from the anode to the cathode) of the varactor. For example, a DC voltage across the anode 104 and cathode 106 may be adjusted to reach a desirable capacitance for an AC signal that is to be passed through the varactor 100.

In the embodiment of FIGS. 1A-1B, the varactor is formed of a strip of HP TFT material 102 that is placed substantially orthogonal to a strip of conductive material forming the anode 104 and a strip of conductive material forming the cathode 106. The strips forming the anode 104 and cathode 106 are substantially parallel to each other.

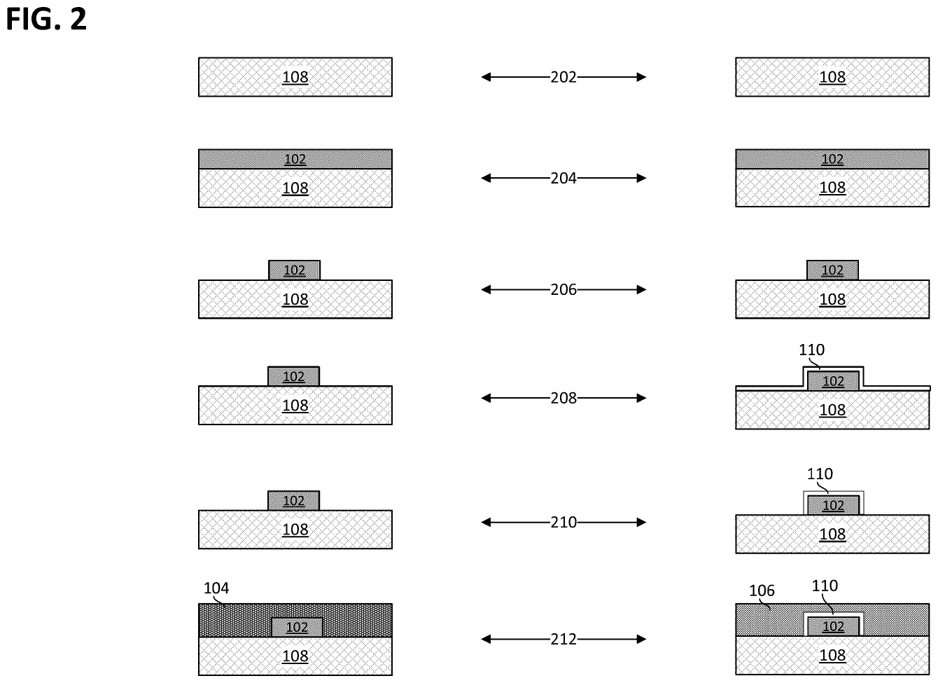

FIG. 2 illustrates phases of manufacture of the varactor 100 of FIGS. 1A-1B, in accordance with any of the embodiments disclosed herein. The structures shown in the left column correspond to a cross section of the varactor at the anode 104 while the structures shown in the right column correspond to a cross section of the varactor at the cathode 106.

At phase 202, the substrate 108 is formed. At phase 204, HP TFT material 102 is formed over the substrate 108. The HP TFT material 102 may be formed in any suitable manner, such as through atomic layer deposition (ALD), chemical vapor deposition (CVD), physical vapor deposition (PVD), or other suitable technique.

At phase 206, portions of the HP TFT material 102 are removed to obtain the desired profile of the HP TFT material. The HP TFT material 102 may be removed in any suitable manner, such as through etching or other suitable technique.

At phase 208, a thin layer of dielectric material 110 is formed over the HP TFT material 102 (and the substrate 108) on the cathode side, but not on the anode side. In some embodiments, this may be accomplished by masking the anode side and then performing deposition of the dielectric material 110.

At phase 210, portions of the dielectric material 110 are removed to obtain the desired profile of the dielectric material (e.g., such that the dielectric material coats the top and sides of the HP TFT material 102 on the cathode side). The dielectric material 110 may be removed in any suitable manner, such as through etching or other suitable technique.

At phase 212, the anode 104 is formed over the substrate 108 and the HP TFT material 102 on the anode side. In some embodiments, an ohmic contact layer may first be formed over at least a portion of the exposed surface of the HP TFT material 102 prior to formation of the anode 104. The cathode 106 is also formed over the substrate 108 and the dielectric material 110 on the cathode side. In some embodiments, the anode 104 and cathode 106 comprise the same material and may be deposited simultaneously. In other embodiments, the anode 104 and cathode 106 may comprise different materials and may be deposited in separate process steps.

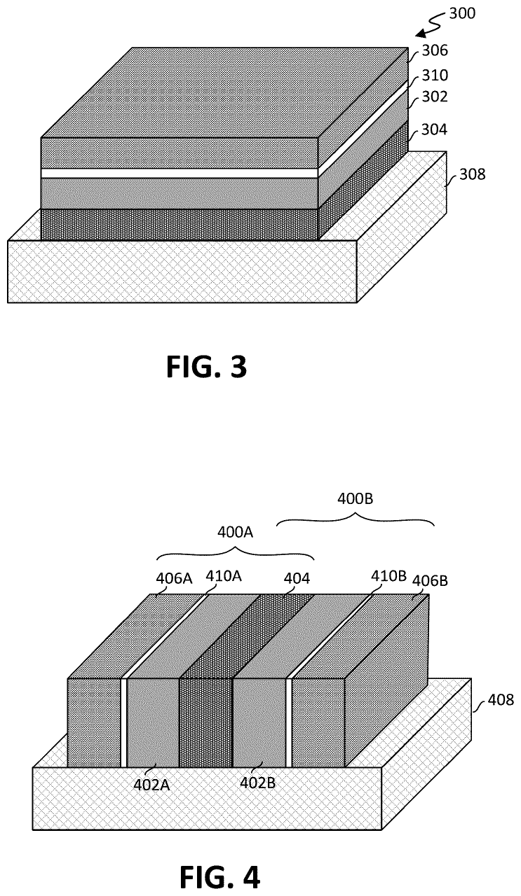

FIG. 3 illustrates a varactor 300 in which HP TFT material 302 is vertically stacked between an anode 304 and cathode 306, in accordance with any of the embodiments disclosed herein. A dielectric material 310 is also stacked between the HP TFT material 302 and the cathode 306. In various embodiments, an ohmic contact material (not shown) may also be stacked between the HP TFT material 302 and the anode 304. The various layers are all stacked on a substrate 308. In this embodiment, the upper surface of an element contacts at least a portion (e.g., a majority of) of the lower surface of another element (in the embodiment depicted the entire upper surface of an element contacts the entire lower surface of the element above it).

In various embodiments, the stack may be repeated any number of times. For example, another substrate 308 may be placed on top of cathode 306 and the stack may be repeated. As another example, another layer of dielectric material 310 may be formed above (e.g., on) the cathode 306, then another layer of HP TFT material 302, then another anode 304, then another layer of HP TFT material 402, then another layer of dielectric material 310, then another cathode 306, and so on. Other orders of stacking of the depicted layers may be utilized depending on the application.

FIG. 4 illustrates varactors 400 (e.g., 400A, 400B) in which HP TFT material 402 (e.g., 402A, 402B) is formed between an anode 404 and a respective cathode 406 (e.g., 406A, 406B) in a horizontal grating configuration, in accordance with any of the embodiments disclosed herein. In this embodiment, the sidewalls of an element touches at least a portion (e.g., a majority of) the sidewalls of adjacent elements (in the embodiment depicted the entire sidewall of an element contacts the entire sidewall of adjacent elements). A dielectric material 410 (e.g., 410A, 410B) is formed between each cathode 406 and the anode 404. In some embodiments, an ohmic contact material (not shown) may be formed between each segment of HP TFT material 402 and the anode 404. The various elements are all stacked on a substrate 408.

In this embodiment, the varactors 400 may share a common anode 404. In various embodiments, varactors 400 may share anodes or cathodes, or may each comprise a distinct anode and cathode. Signal lines may be coupled to the anodes and cathodes in any suitable manner to form varactors 400 in series, varactors 400 in parallel, etc. In other embodiments, additional elements may be formed on either side (or both sides) of the elements in the horizontal grating configuration on the substrate 408 to form any number of adjacent varactors 400.

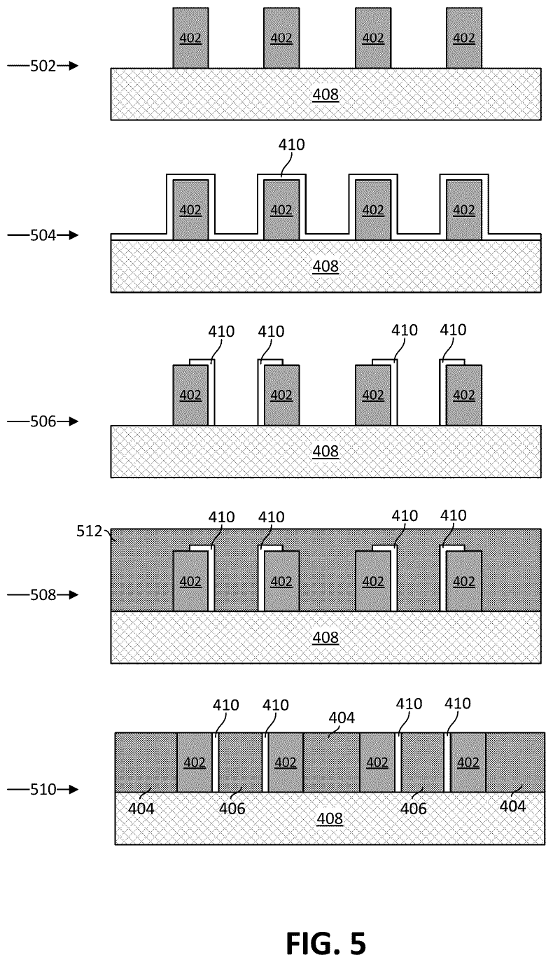

FIG. 5 illustrates phases of manufacture of varactors in a horizontal grating configuration, in accordance with any of the embodiments disclosed herein.

At phase 502, discrete segments of HP TFT material 402 are deposited on a substrate 408. At phase 504, a layer of dielectric material 410 is deposited over the substrate 408 and the segments of HP TFT material 402.

At phase 506, unwanted portions of the dielectric material 410 are removed. For example, portions that run between the eventual anodes 404 and adjacent segments of HP TFT material 402 may be removed (e.g., by etching). Some portions of the dielectric material 410 may remain in some upper corner regions of the HP TFT material 402 as an artifact of the removal process (these portions will be removed in a future step).

At phase 508, a conductive material 512 is deposited. The conductive material 512 may be deposited between the adjacent segments of HP TFT material 402. In this embodiment, the same conductive material 512 is used for the eventual anodes and cathodes. In other embodiments, different conductive materials (e.g., one for the anodes and another one for the cathodes) could be deposited in multiple process steps.

At phase 510, unwanted portions of the conductive material 512 (and any remaining undesired dielectric material 410) are removed (e.g., via etch or polishing) to form the varactors comprising anodes 404 and cathodes 406.

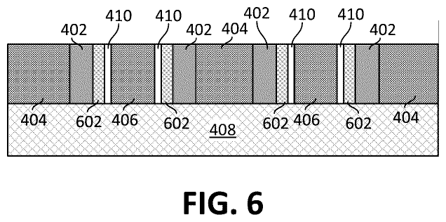

FIG. 6 illustrates the varactors formed by the process of FIG. 5 with modulated depletion regions 602, in accordance with any of the embodiments disclosed herein. When a voltage is applied across the anode 404 and cathode 406 of a varactor, a depletion region 602 at the interface between the cathode 406 and the adjacent HP TFT material 402 (e.g., within a portion of the HP TFT material 402) is modulated. In the depletion region, mobile charge carriers (free electrons and holes) may be absent (and immobile positive and negative ions may be present). A depletion region 602 blocks electric current, thus causing the varactor to exhibit a capacitive effect. Modulation of the depletion region by changing the voltage applied may result in a change of the width of the depletion region and a resulting change in capacitance of the varactor (as the capacitance may be inversely proportional to the width of the depletion region).

As described above, the material formed between a cathode and anode (which may include the depletion region) of a varactor comprises HP TFT material (e.g., 102, 302, 402). In some embodiments, the HP TFT material (also referred to herein as a HP TFT channel material) is a material that is suitable for use as a channel material in a TFT. Indeed, in some embodiments, an integrated circuit device that includes one or more varactors as described herein also includes TFTs with the HP TFT material as a channel material. In general, a TFT is a special kind of a field-effect transistor made by depositing a thin-film of an active semiconductor material (e.g., an HP TFT material), as well as a dielectric layer and metallic contacts, over a support layer that may be a non-conducting layer. At least a portion of the active semiconductor material forms a channel of the TFT, through which charge carriers (e.g., electrons or holes) flow from a source to a drain of the transistor. This differs from conventional, non-TFT, front-end-of-line (FEOL) logic transistors where the active semiconductor channel material is typically a part of a semiconductor substrate, e.g., a part of a silicon wafer. In various embodiments, the TFTs may be formed in the same plane as the FEOL logic transistors. In other embodiments, since an HP TFT material may be deposited at a relatively low temperature, the HP TFT may be deposited within the thermal budgets imposed on back end fabrication to avoid damaging the front end components (e.g., FEOL logic transistors) and thus may be formed in the back-end-of-line (BEOL) regions. In yet other embodiments, the TFTs may be formed on the back side of a wafer.

In various embodiments, the HP TFT material may be deposited using atomic layer deposition (ALD), chemical vapor deposition (CVD), or physical vapor deposition (PVD), or other suitable technique. In various embodiments, the HP TFT material is a versatile material that can be grown on any suitable substrate (e.g., 108, 308, 408) such as a crystalline or a non-crystalline structure (e.g., a dielectric material, such as silicon oxide, silicon nitride, metal oxide, silicon oxynitride, etc.) or other varactor material (e.g., an anode or dielectric material). Thus, the HP TFT material may be grown independent of a semiconductor substrate in particular embodiments.

An HP TFT material may comprise a semiconductor material exhibiting a high mobility and a wide bandgap voltage. In various embodiments, the HP TFT material is not a single crystalline material (e.g., silicon), but is amorphous, polycrystalline, or nanocrystalline.

In various embodiments, the charge carrier mobility of the HP TFT material is higher than 5 cm cm²/(V·s), higher than 20 cm²/(V·s), higher than 50 cm²/(V·s), or higher than 100 cm²/(V·s). In various embodiments, the mobility of the HP TFT material is between 5 cm²/(V·s) and 700 cm²/(V·s), including all values and ranges therein (including the range from 50 cm²/(V·s) to 700 cm²/(V·s) and the range from 100 cm²/(V·s) to 700 cm²/(V·s)). At least in some embodiments, these ranges may be critical as they represent a range for mobility that is high enough to function as an HP TFT channel material, which is generally difficult to achieve with an amorphous, nanocrystalline, or polycrystalline material.

In various embodiments, the bandgap voltage of the HP TFT material is higher than the bandgap voltage of silicon (e.g., 1.14 eV @ 300K). In some examples, the bandgap voltage of the HP TFT material is materially higher than the bandgap voltage of silicon (e.g., higher than 1.2 cV @ 300K). In particular embodiments, the bandgap voltage of the HP TFT material is higher than the bandgap voltage of silicon but lower than 6.5 eV @ 300K, including all values and ranges therein. In various embodiments, the bandgap voltage of the HP TFT material is higher than the bandgap voltage of a substrate upon which a transistor comprising the HP TFT material is formed. In some embodiments, these ranges may be critical as they represent a range for a bandgap voltage that may protect against channel breakdown.

In various embodiments, the HP TFT material comprises an oxide (e.g., a metal oxide), such as indium gallium zinc oxide (IGZO), indium tin oxide (ITO), indium xinc oxide (IZO), zinc oxide, indium oxide, gallium oxide, copper oxide, tin oxide, or other suitable oxide. In some oxides, a material with insulating properties may be introduced into the oxide to increase the bandgap voltage. For example, doping indium oxide with hafnium oxide (which exhibits insulating properties) will result in a composite HP TFT material with a wider bandgap than the indium oxide. Similarly, indium oxide or zinc oxide may be doped with gallium oxide (which exhibits insulating properties) to produce a composite HP TFT material with a wider bandgap voltage.

In some embodiments, the HP TFT material comprises a nitride (e.g., a metal nitride), such as zinc nitride, indium nitride, gallium nitride, copper nitride, aluminum nitride, or other suitable nitride. In some nitrides, a material with insulating properties may be introduced into the nitride to increase the bandgap voltage. For example, aluminum nitride (which exhibits insulating properties) may be added to indium nitride, zinc nitride, or gallium nitride to produce a composite HP TFT material with an increased bandgap voltage.

In some embodiments, the HP TFT material comprises a chalcogenide, such as a selenide or sulfide of molybdenum, tungsten, indium, gallium, zinc, copper, hafnium, aluminum, or germanium.

In some embodiments, the HP TFT material comprises any other suitable material, such as black phosphorous, graphene, carbon nanotubes, polysilicon, poly germanium, poly (3,5) (gallium arsenide, etc.). While some of these materials have a narrower bandgap voltage than silicon in certain compositions, the concentration of certain elements (e.g., gallium) may be increased to improve the bandgap voltage of the resulting HP TFT material.

A conductive contact (e.g., anode 104, 304, 404, cathode 106, 306, 406) may include any suitable conductive material such as polysilicon, a metal, a metal alloy, or carbides, oxides, and nitrides thereof. Example suitable conductive contact materials may comprise aluminum, tungsten, cobalt, molybdenum, ruthenium, titanium, tantalum, copper, gold, palladium, platinum, nickel, hafnium, zirconium, titanium, tantalum, etc.

A dielectric material (e.g., 110, 310, 410) may be provided to separate (e.g., to be between) the HP TFT material and a metal contact (e.g., a cathode). In various embodiments, a dielectric material may include (in addition to the examples provided above for materials on which the HP TFT material may be grown) one or more high-k dielectric materials and may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate.

In one example, a varactor described herein may comprise an HP TFT material comprising a nitride (e.g., InN, InZnN, GaN, InGaN with oxygen, sulphur and/or phosphorus additions). In another example, the varactor may comprise an HP TFT material comprising a ZnN film with a bandgap voltage ranging from 1.3 to 3 cV (depending on the N content) with a mobility exceeding 100 cm²/Vs. The varactor may also comprise a dielectric material comprising HfZrOx and/or a conductive contact comprising Ta, Ti, TiN or W.

A substrate (e.g., 108, 308, 408) for a varactor may comprise any suitable dielectric material such as a crystalline or a non-crystalline structure (e.g., such as silicon oxide, silicon nitride, a metal oxide (e.g., aluminum oxide), other oxide, or silicon oxynitride, etc.). In some embodiments, a non-crystalline substrate may refer to a wafer or thin templating layer that is amorphous, polycrystalline, or nanocrystalline (e.g., each nanocrystallite grain not exceeding 1 nanometer), e.g., it has a short range order. The non-crystalline substrate may be a layer or a bulk substrate.

Various elements of the components described herein (e.g., HP TFT material, cathodes, anodes, dielectric materials, substrates, ohmic contact layers, etc.) with respect to one or more particular FIGs. may have any suitable characteristics of corresponding elements described with respect to other FIGs. or elsewhere herein.

Transistors (e.g., TFTs, non-TFT transistors) that may be included in the same integrated device as one or more varactors may include various components, including one or more of a substrate, S/D electrodes, gate electrodes, gate dielectrics, a channel material (e.g., HP TFT material, the substrate material, etc.). Various examples for such components are now described.

A substrate used, e.g., for formation of transistors may be, for example, a bulk substrate including group IV semiconductor material (such as silicon, germanium, or silicon germanium), group III-V semiconductor material (such as gallium arsenide, indium gallium arsenide, or indium phosphide), and/or any other suitable material from and/or upon which transistors can be formed. Alternatively, the substrate can be a semiconductor-on-insulator substrate having a desired semiconductor layer over a buried insulator layer (e.g., silicon over silicon dioxide). Alternatively, the substrate can be a multilayer substrate or superlattice suitable for forming nanowires or nanoribbons (e.g., alternating layers of silicon and SiGe, or alternating layers of indium gallium arsenide and indium phosphide).

The S/D electrodes may be coupled to a channel material. As is commonly known, source and drain terminals are interchangeable in transistors (hence, the notation “S/D” terminals is sometimes used, indicating the interchangeability of the source and drain terminals). Therefore, while some examples and illustrations may be presented here with reference to source and drain electrodes, in other embodiments, any of source or drain terminals may be reversed.

S/D electrodes may include any suitable electrically conductive material, alloy, or a stack of multiple electrically conductive materials. In some embodiments, the S/D electrodes may include one or more metals or metal alloys, comprising one or metals, e.g., copper, ruthenium, palladium, platinum, cobalt, nickel, hafnium, zirconium, titanium, tantalum, and aluminum, tantalum nitride, titanium nitride, tungsten, doped silicon, doped germanium, or alloys and mixtures of these. In some embodiments, the S/D electrodes may include one or more electrically conductive alloys, oxides, or carbides of one or more metals. In some embodiments, the S/D electrodes may include a doped semiconductor, such as silicon or another semiconductor doped with an N-type dopant or a P-type dopant. Metals may provide higher conductivity, while doped semiconductors may be easier to pattern during fabrication.

A gate dielectric may be provided to separate (e.g., to be between) the channel material and the gate electrode. In various embodiments, a gate dielectric may include one or more high-k dielectric materials and may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, an annealing process may be carried out on the gate dielectric to improve its quality when a high-k material is used.

In some cases, a gate dielectric may include multiple layers, such as a first layer of high-k material (e.g., hafnium oxide) in contact with a gate electrode and a second layer of lower-k oxide between the first layer and the channel material. The lower-k oxide may be, for instance, silicon oxide or an oxide of the channel layer material. In various embodiments, the one or more layers of a gate dielectric may include e.g., silicon oxide, silicon dioxide, silicon carbide, and/or a high-k dielectric material.

A gate electrode may include any suitable conductive material such as polysilicon, a metal, or a metal alloy. Example suitable metals or metal alloys include aluminum, tungsten, cobalt, molybdenum, ruthenium, titanium, tantalum, copper, and carbides and nitrides thereof. In various embodiments, a gate electrode may include at least one P-type work function metal or N-type work function metal, depending on whether the respective transistor is a P-type transistor or an N-type transistor. For a P type transistor, metals that may be used for the gate electrode may include, but are not limited to, ruthenium, gold, palladium, platinum, cobalt, nickel, and conductive metal oxides (e.g., ruthenium oxide). For an N type transistor, metals that may be used for the gate electrode include, but are not limited to, hafnium, zirconium, titanium, tantalum, aluminum, alloys of these metals, and carbides and nitrides of these metals (e.g., hafnium carbide, zirconium carbide, titanium carbide, tantalum carbide, aluminum carbide, titanium nitride, and tantalum nitride).

In some embodiments, the gate electrode may include a stack of two or more metal layers, where one or more metal layers are work function metal layers and at least one metal layer is a fill metal layer or inner plug layer. Further metal layers may be included for other purposes, such as to act as a diffusion barrier layer.

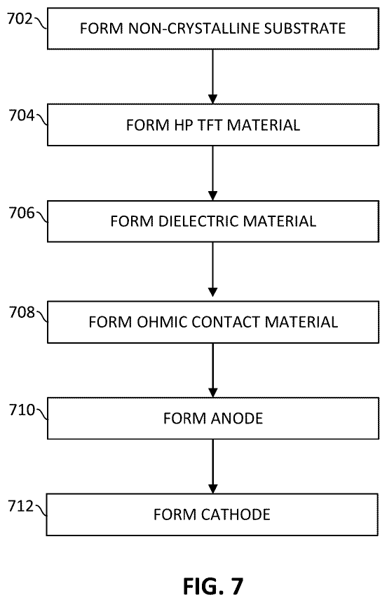

FIG. 7 illustrates a method for forming a varactor, in accordance with any of the embodiments disclosed herein. At 702, a non-crystalline substrate is formed. In some embodiments, this substrate may be formed on the back side of a wafer, after logic on the front end has been fabricated. At 704, an HP TFT material is formed. At 706, a dielectric material is formed in contact with a portion of the HP TFT material. At 708, ohmic contact material is formed in contact with another portion of the HP TFT material. At 710, an anode is formed (e.g., in contact with the ohmic contact material. At 712, a cathode is formed (e.g., in contact with the dielectric material). The operations and suboperations of FIG. 7 may be performed in any suitable order.

Although particular references are made to anodes and cathodes herein, in various embodiments the roles of the anodes and cathodes may be interchangeable and thus the disclosure contemplates any suitable arrangements of these elements.

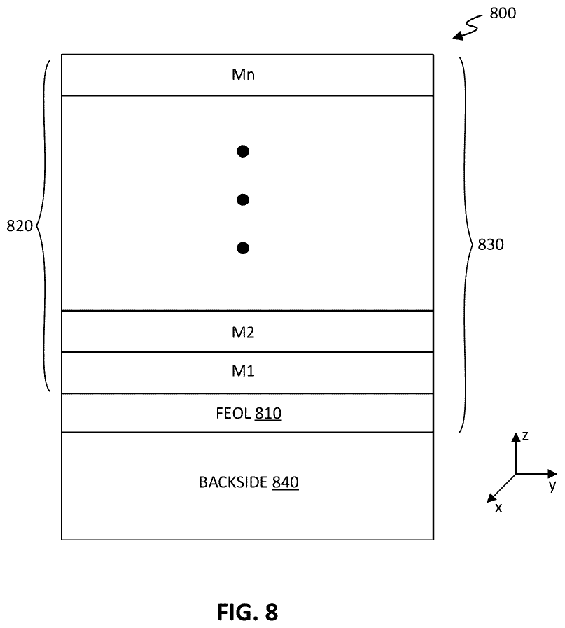

FIG. 8 provides a schematic illustration of a cross-sectional view of an example integrated circuit device (e.g., a chip) 800, according to some embodiments of the present disclosure. The IC device 800 may include transistors as well as varactors with channel material comprising an HP TFT material.

As shown in FIG. 8, the IC device 800 may include a front side 830 comprising an FEOL 810 that includes various logic layers, circuits, and devices to drive and control a logic IC. These circuits and devices may be configured for any number of functions, such as logic or compute transistors, input/output (I/O) transistors, access or switching transistors, and/or radio frequency (RF) transistors, to name a few examples. According to some embodiments, in addition to these devices and circuits, FEOL 810 may include, for example, one or more other layers or structures associated with the semiconductor devices and circuits. For example, the FEOL can also include a substrate and one or more dielectric layers that surround active and/or conductive portions of the devices and circuits. The FEOL may also include one or more conductive contacts that provide electrical contact to transistor elements such as gate structures, drain regions, or source regions. The FEOL may also include local interconnect (e.g., vias or lines) that connect contacts to interconnect features within the BEOL 820.

The front side 830 of the IC device 800 also includes a BEOL 820 including various metal interconnect layers (e.g., metal 1 through metal n, where n is any suitable integer). Various metal layers of the BEOL 820 may be used to interconnect the various inputs and outputs of the FEOL 810.

Generally speaking, each of the metal layers of the BEOL 820, e.g., each of the layers M1-Mn shown in FIG. 8, may include a via portion and a trench/interconnect portion. Typically, the trench portion of a metal layer is above the via portion, but, in other embodiments, a trench portion may be provided below a via portion of any given metal layer of the BEOL 820. The trench portion of a metal layer may be configured for transferring signals and power along metal lines (also sometimes referred to as “trenches”) extending in the x-y plane (e.g., in the x or y directions), while the via portion of a metal layer may be configured for transferring signals and power through metal vias extending in the z-direction, e.g., to any of the adjacent metal layers above or below. Accordingly, vias connect metal structures (e.g., metal lines or vias) from one metal layer to metal structures of an adjacent metal layer. While referred to as “metal” layers, various layers of the BEOL 820, e.g., layers M1-Mn shown in FIG. 8, may include certain patterns of conductive metals, e.g., copper (Cu) or aluminum (Al), or metal alloys, or more generally, patterns of an electrically conductive material, formed in an insulating medium such as an interlayer dielectric (ILD). The insulating medium may include any suitable ILD materials such as silicon oxide, silicon nitride, aluminum oxide, and/or silicon oxynitride. In various embodiments, any one or more of these layers may additionally include active devices (e.g., transistors, diodes) and/or passive devices (e.g., capacitors, resistors, inductors).

The IC device 800 may also include a backside 840. For example, the backside 840 may formed on the opposite side of a wafer from the front side 830. In various embodiments, the backside 840 may include any suitable elements to assist operation of the IC device 800. For example, the backside 840 may include various metal layers to deliver power to logic of the FEOL 810. In some embodiments, transistors or other circuit elements (e.g., varactors 100, 300, 400) including HP TFT material may be formed on the backside 840 of the IC device 800.

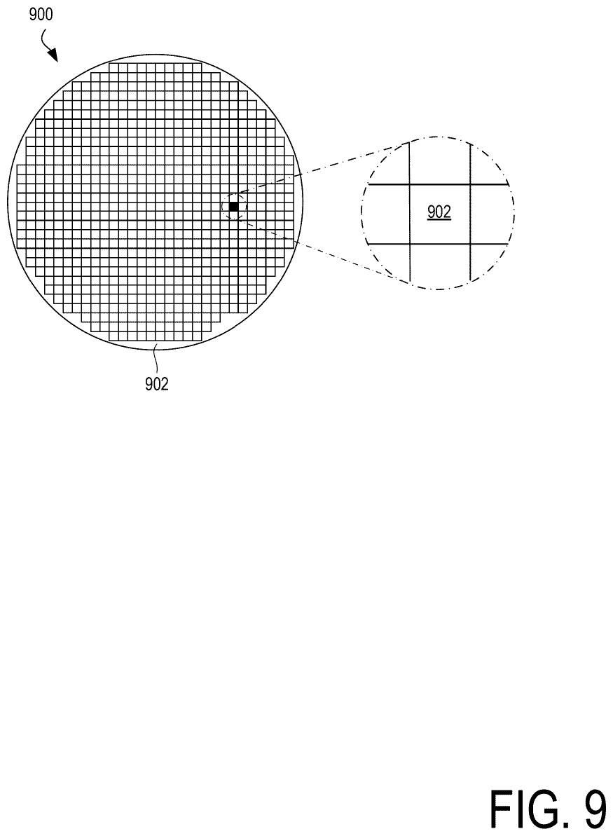

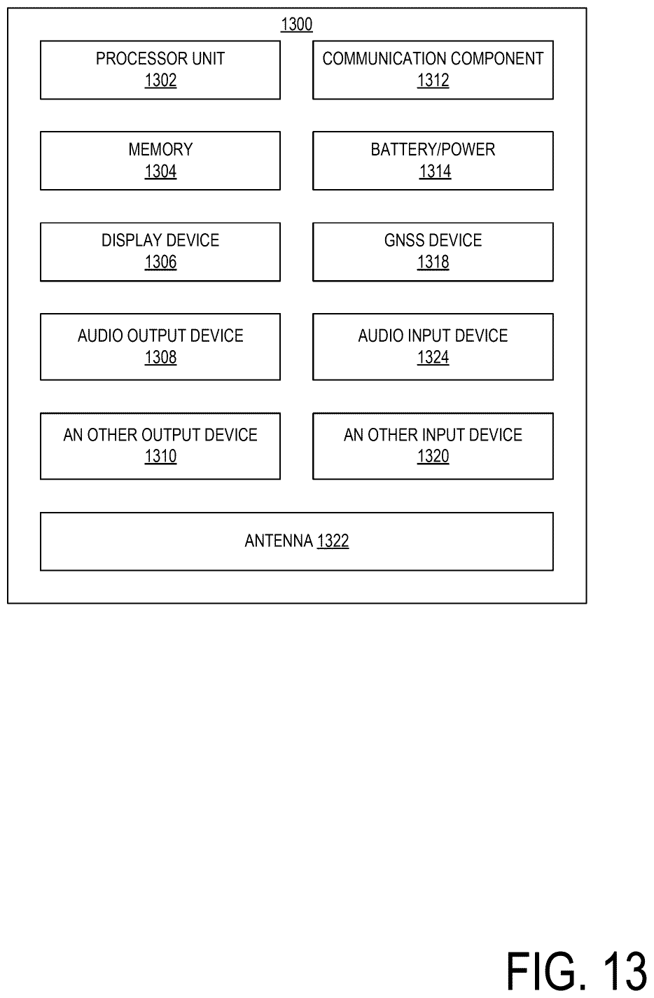

FIG. 9 is a top view of a wafer 900 and dies 902 wherein individual dies may include varactors as described herein. The wafer 900 may be composed of semiconductor material and may include one or more dies 902 having integrated circuit structures formed on a surface of the wafer 900. The individual dies 902 may be a repeating unit of an integrated circuit product that includes any suitable integrated circuit. After the fabrication of the semiconductor product is complete, the wafer 900 may undergo a singulation process in which the dies 902 are separated from one another to provide discrete “chips” of the integrated circuit product. The die 902 may include one or more transistors, supporting circuitry to route electrical signals to the transistors, passive components (e.g., signal traces, resistors, capacitors, or inductors), and/or any other integrated circuit components. In some embodiments, the wafer 900 or the die 902 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, OTP RAM, etc.), a logic device (e.g., an AND, OR, NAND, or NOR gate), or any other suitable circuit element. Multiple ones of these devices may be combined on a single die 902. For example, a memory array formed by multiple memory devices may be formed on a same die 902 as a processor unit (e.g., the processor unit 1302 of FIG. 13) or other logic that is configured to store information in the memory devices or execute instructions stored in the memory array.

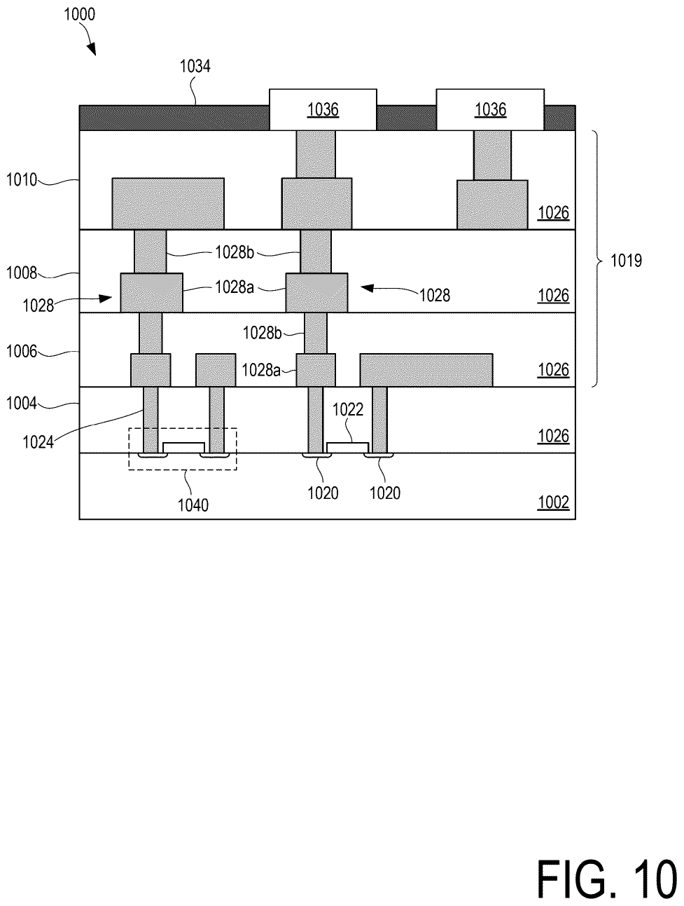

FIG. 10 is a cross-sectional side view of an integrated circuit device 1000 that may include varactors as described herein. One or more of the integrated circuit devices 1000 may be included in one or more dies 902 (FIG. 9). The integrated circuit device 1000 may be formed on a die substrate 1002 (e.g., the wafer 900 of FIG. 9) and may be included in a die (e.g., the die 902 of FIG. 9). The die substrate 1002 may be a semiconductor substrate composed of semiconductor material systems including, for example, n-type or p-type materials systems (or a combination of both). The die substrate 1002 may include, for example, a crystalline substrate formed using a bulk silicon or a silicon-on-insulator (SOI) substructure. In some embodiments, the die substrate 1002 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI. III-V, or IV may also be used to form the die substrate 1002. Although a few examples of materials from which the die substrate 1002 may be formed are described here, any material that may serve as a foundation for an integrated circuit device 1000 may be used. The die substrate 1002 may be part of a singulated die (e.g., the dies 902 of FIG. 9) or a wafer (e.g., the wafer 900 of FIG. 9).

The integrated circuit device 1000 may include one or more device layers 1004 disposed on the die substrate 1002. The device layer 1004 may include features of one or more transistors 1040 (e.g., metal oxide semiconductor field-effect transistors (MOSFETs)) formed on the die substrate 1002. The transistors 1040 may include, for example, one or more source and/or drain (S/D) regions 1020, a gate 1022 to control current flow between the S/D regions 1020, and one or more S/D contacts 1024 to route electrical signals to/from the S/D regions 1020. The transistors 1040 may include additional features not depicted for the sake of clarity, such as device isolation regions, gate contacts, and the like. The transistors 1040 are not limited to the type and configuration depicted in FIG. 10 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

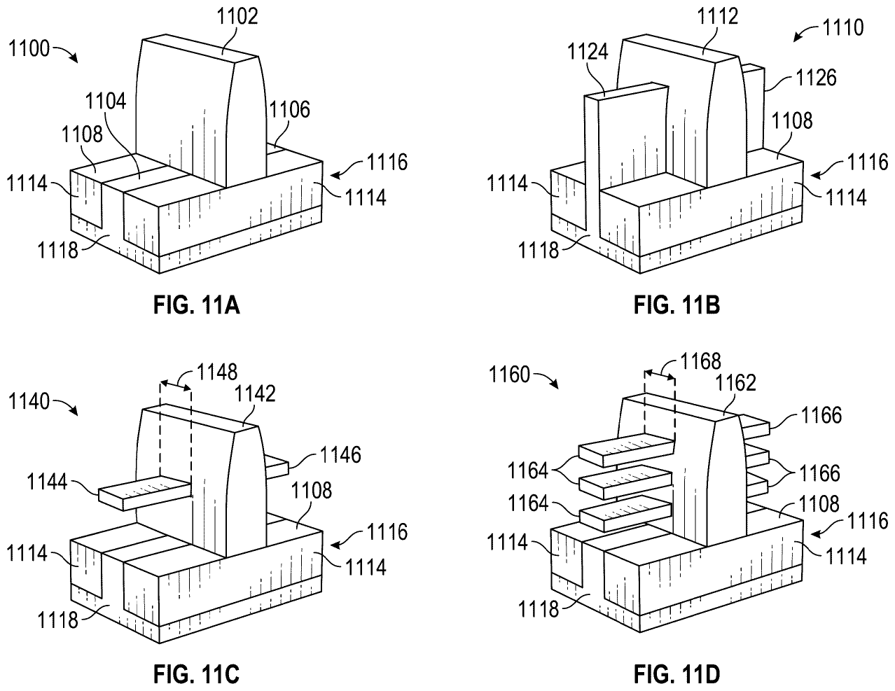

FIGS. 11A-11D are simplified perspective views of example planar, FinFET, gate-all-around, and stacked gate-all-around transistors. The transistors illustrated in FIGS. 11A-11D are formed on a substrate 1116 having a surface 1108. Isolation regions 1114 separate the source and drain regions of the transistors from other transistors and from a bulk region 1118 of the substrate 1116.

FIG. 11A is a perspective view of an example planar transistor 1100 comprising a gate 1102 that controls current flow between a source region 1104 and a drain region 1106. The transistor 1100 is planar in that the source region 1104 and the drain region 1106 are planar with respect to the substrate surface 1108.

FIG. 11B is a perspective view of an example FinFET transistor 1120 comprising a gate 1122 that controls current flow between a source region 1124 and a drain region 1126. The transistor 1120 is non-planar in that the source region 1124 and the drain region 1126 comprise “fins” that extend upwards from the substrate surface 1128. As the gate 1122 encompasses three sides of the semiconductor fin that extends from the source region 1124 to the drain region 1126, the transistor 1120 can be considered a tri-gate transistor. FIG. 11B illustrates one S/D fin extending through the gate 1122, but multiple S/D fins can extend through the gate of a FinFET transistor.

FIG. 11C is a perspective view of a gate-all-around (GAA) transistor 1140 comprising a gate 1142 that controls current flow between a source region 1144 and a drain region 1146. The transistor 1140 is non-planar in that the source region 1144 and the drain region 1146 are elevated from the substrate surface 1128.

FIG. 11D is a perspective view of a GAA transistor 1160 comprising a gate 1162 that controls current flow between multiple elevated source regions 1164 and multiple elevated drain regions 1166. The transistor 1160 is a stacked GAA transistor as the gate controls the flow of current between multiple elevated S/D regions stacked on top of each other. The transistors 1140 and 1160 are considered gate-all-around transistors as the gates encompass all sides of the semiconductor portions that extends from the source regions to the drain regions. The transistors 1140 and 1160 can alternatively be referred to as nanowire, nanosheet, or nanoribbon transistors depending on the width (e.g., widths 1148 and 1168 of transistors 1140 and 1160, respectively) of the semiconductor portions extending through the gate.

Returning to FIG. 10, a transistor 1040 may include a gate 1022 formed of at least two layers, a gate dielectric and a gate electrode. Examples and characteristics of gate dielectrics and gate electrodes have been described above.

In some embodiments, when viewed as a cross-section of the transistor 1040 along the source-channel-drain direction, the gate electrode may consist of a U-shaped structure that includes a bottom portion substantially parallel to the surface of the die substrate 1002 and two sidewall portions that are substantially perpendicular to the top surface of the die substrate 1002. In other embodiments, at least one of the metal layers that form the gate electrode may simply be a planar layer that is substantially parallel to the top surface of the die substrate 1002 and does not include sidewall portions substantially perpendicular to the top surface of the die substrate 1002. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1020 may be formed within the die substrate 1002 adjacent to the gate 1022 of individual transistors 1040. The S/D regions 1020 may be formed using an implantation/diffusion process or an etching/deposition process, for example. In the former process, dopants such as boron, aluminum, antimony, phosphorous, or arsenic may be ion-implanted into the die substrate 1002 to form the S/D regions 1020. An annealing process that activates the dopants and causes them to diffuse farther into the die substrate 1002 may follow the ion-implantation process. In the latter process, the die substrate 1002 may first be etched to form recesses at the locations of the S/D regions 1020. An epitaxial deposition process may then be carried out to fill the recesses with material that is used to fabricate the S/D regions 1020. In some implementations, the S/D regions 1020 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1020 may be formed using one or more alternate semiconductor materials such as germanium or a group III-V material or alloy. In further embodiments, one or more layers of metal and/or metal alloys may be used to form the S/D regions 1020. Further examples of materials that may be used to form the S/D regions are provided above.

Electrical signals, such as power and/or input/output (I/O) signals, may be routed to and/or from the devices (e.g., transistors 1040) of the device layer 1004 through one or more interconnect layers disposed on the device layer 1004 (illustrated in FIG. 10 as interconnect layers 1006-1010). For example, electrically conductive features of the device layer 1004 (e.g., the gate 1022 and the S/D contacts 1024) may be electrically coupled with the interconnect structures 1028 of the interconnect layers 1006-1010. The one or more interconnect layers 1006-1010 may form a metallization stack (also referred to as an “ILD stack”) 1019 of the integrated circuit device 1000.

The interconnect structures 1028 may be arranged within the interconnect layers 1006-1010 to route electrical signals according to a wide variety of designs; in particular, the arrangement is not limited to the particular configuration of interconnect structures 1028 depicted in FIG. 10. Although a particular number of interconnect layers 1006-1010 is depicted in FIG. 10, embodiments of the present disclosure include integrated circuit devices having more or fewer interconnect layers than depicted.

In some embodiments, the interconnect structures 1028 may include lines 1028a and/or vias 1028b filled with an electrically conductive material such as a metal. The lines 1028a may be arranged to route electrical signals in a direction of a plane that is substantially parallel with a surface of the die substrate 1002 upon which the device layer 1004 is formed. For example, the lines 1028a may route electrical signals in a direction in and out of the page. The vias 1028b may be arranged to route electrical signals in a direction of a plane that is substantially perpendicular to the surface of the die substrate 1002 upon which the device layer 1004 is formed. In some embodiments, the vias 1028b may electrically couple lines 1028a of different interconnect layers 1006-1010 together.

The interconnect layers 1006-1010 may include a dielectric material 1026 disposed between the interconnect structures 1028, as shown in FIG. 10. In some embodiments, dielectric material 1026 disposed between the interconnect structures 1028 in different ones of the interconnect layers 1006-1010 may have different compositions; in other embodiments, the composition of the dielectric material 1026 between different interconnect layers 1006-1010 may be the same. The device layer 1004 may include a dielectric material 1026 disposed between the transistors 1040 and a bottom layer of the metallization stack as well. The dielectric material 1026 included in the device layer 1004 may have a different composition than the dielectric material 1026 included in the interconnect layers 1006-1010; in other embodiments, the composition of the dielectric material 1026 in the device layer 1004 may be the same as a dielectric material 1026 included in any one of the interconnect layers 1006-1010.

A first interconnect layer 1006 (referred to as Metal 1 or “M1”) may be formed directly on the device layer 1004. In some embodiments, the first interconnect layer 1006 may include lines 1028a and/or vias 1028b, as shown. The lines 1028a of the first interconnect layer 1006 may be coupled with contacts (e.g., the S/D contacts 1024) of the device layer 1004. The vias 1028b of the first interconnect layer 1006 may be coupled with the lines 1028a of a second interconnect layer 1008.

The second interconnect layer 1008 (referred to as Metal 2 or “M2”) may be formed directly on the first interconnect layer 1006. In some embodiments, the second interconnect layer 1008 may include via 1028b to couple the lines 1028 of the second interconnect layer 1008 with the lines 1028a of a third interconnect layer 1010. Although the lines 1028a and the vias 1028b are structurally delineated with a line within individual interconnect layers for the sake of clarity, the lines 1028a and the vias 1028b may be structurally and/or materially contiguous (e.g., simultaneously filled during a dual-damascene process) in some embodiments.

The third interconnect layer 1010 (referred to as Metal 3 or “M3”) (and additional interconnect layers, as desired) may be formed in succession on the second interconnect layer 1008 according to similar techniques and configurations described in connection with the second interconnect layer 1008 or the first interconnect layer 1006. In some embodiments, the interconnect layers that are “higher up” in the metallization stack 1019 in the integrated circuit device 1000 (e.g., farther away from the device layer 1004) may be thicker that the interconnect layers that are lower in the metallization stack 1019, with lines 1028a and vias 1028b in the higher interconnect layers being thicker than those in the lower interconnect layers.

The integrated circuit device 1000 may include a solder resist material 1034 (e.g., polyimide or similar material) and one or more conductive contacts 1036 formed on the interconnect layers 1006-1010. In FIG. 10, the conductive contacts 1036 are illustrated as taking the form of bond pads. The conductive contacts 1036 may be electrically coupled with the interconnect structures 1028 and configured to route the electrical signals of the transistor(s) 1040 to external devices. For example, solder bonds may be formed on the one or more conductive contacts 1036 to mechanically and/or electrically couple an integrated circuit die including the integrated circuit device 1000 with another component (e.g., a printed circuit board). The integrated circuit device 1000 may include additional or alternate structures to route the electrical signals from the interconnect layers 1006-1010; for example, the conductive contacts 1036 may include other analogous features (e.g., posts) that route the electrical signals to external components.

In some embodiments in which the integrated circuit device 1000 is a double-sided die, the integrated circuit device 1000 may include another metallization stack (not shown) on the opposite side of the device layer(s) 1004. This metallization stack may include multiple interconnect layers as discussed above with reference to the interconnect layers 1006-1010, to provide conductive pathways (e.g., including conductive lines and vias) between the device layer(s) 1004 and additional conductive contacts (not shown) on the opposite side of the integrated circuit device 1000 from the conductive contacts 1036.

In other embodiments in which the integrated circuit device 1000 is a double-sided die, the integrated circuit device 1000 may include one or more through silicon vias (TSVs) through the die substrate 1002; these TSVs may make contact with the device layer(s) 1004, and may provide conductive pathways between the device layer(s) 1004 and additional conductive contacts (not shown) on the opposite side of the integrated circuit device 1000 from the conductive contacts 1036. In some embodiments, TSVs extending through the substrate can be used for routing power and ground signals from conductive contacts on the opposite side of the integrated circuit device 1000 from the conductive contacts 1036 to the transistors 1040 and any other components integrated into the integrated circuit device (e.g., die) 1000, and the metallization stack 1019 can be used to route I/O signals from the conductive contacts 1036 to transistors 1040 and any other components integrated into the integrated circuit device (e.g., die) 1000.

Multiple integrated circuit devices 1000 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

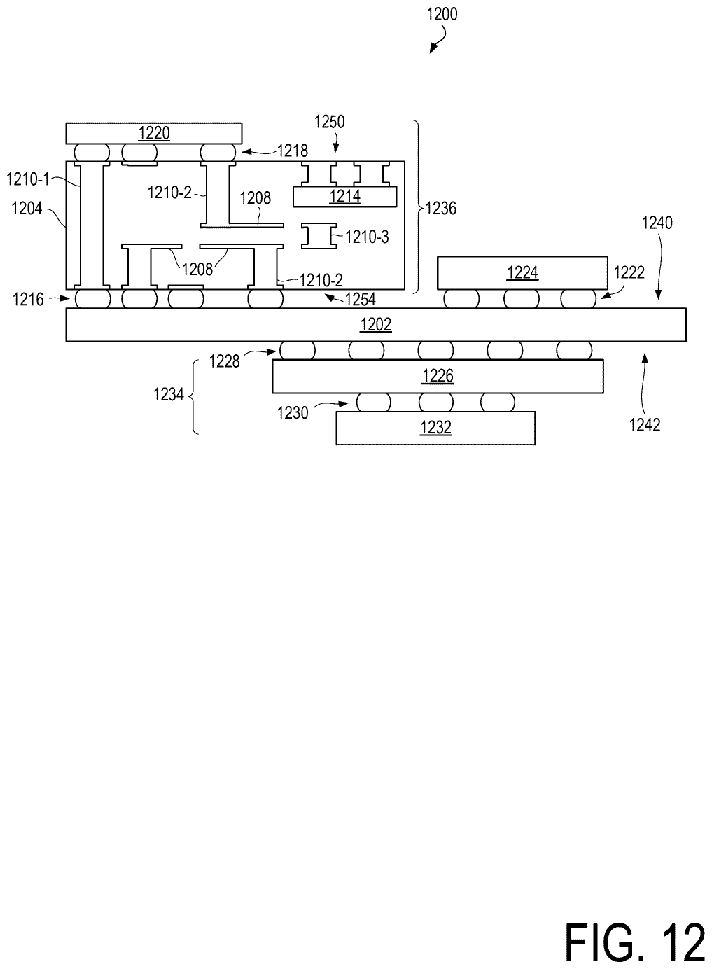

FIG. 12 is a cross-sectional side view of an integrated circuit device assembly 1200. The integrated circuit device assembly 1200 includes a number of components disposed on a circuit board 1202 (which may be a motherboard, system board, mainboard, etc.). The integrated circuit device assembly 1200 includes components disposed on a first face 1240 of the circuit board 1202 and an opposing second face 1242 of the circuit board 1202; generally, components may be disposed on one or both faces 1240 and 1242.

In some embodiments, the circuit board 1202 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1202. In other embodiments, the circuit board 1202 may be a non-PCB substrate. The integrated circuit device assembly 1200 illustrated in FIG. 12 includes a package-on-interposer structure 1236 coupled to the first face 1240 of the circuit board 1202 by coupling components 1216. The coupling components 1216 may electrically and mechanically couple the package-on-interposer structure 1236 to the circuit board 1202, and may include solder balls (as shown in FIG. 12), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1236 may include an integrated circuit component 1220 coupled to an interposer 1204 by coupling components 1218. The coupling components 1218 may take any suitable form for the application, such as the forms discussed above with reference to the coupling components 1216. Although a single integrated circuit component 1220 is shown in FIG. 12, multiple integrated circuit components may be coupled to the interposer 1204; indeed, additional interposers may be coupled to the interposer 1204. The interposer 1204 may provide an intervening substrate used to bridge the circuit board 1202 and the integrated circuit component 1220.

The integrated circuit component 1220 may be a packaged or unpacked integrated circuit product that includes one or more integrated circuit dies (e.g., the die 902 of FIG. 9, the integrated circuit device 1000 of FIG. 10, etc.) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1220, a single monolithic integrated circuit die comprises solder bumps attached to contacts on the die. The solder bumps allow the die to be directly attached to the interposer 1204. The integrated circuit component 1220 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1220 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1220 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1220 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1204 may spread connections to a wider pitch or reroute a connection to a different connection. For example, the interposer 1204 may couple the integrated circuit component 1220 to a set of ball grid array (BGA) conductive contacts of the coupling components 1216 for coupling to the circuit board 1202. In the embodiment illustrated in FIG. 12, the integrated circuit component 1220 and the circuit board 1202 are attached to opposing sides of the interposer 1204; in other embodiments, the integrated circuit component 1220 and the circuit board 1202 may be attached to a same side of the interposer 1204. In some embodiments, three or more components may be interconnected by way of the interposer 1204.

In some embodiments, the interposer 1204 may be formed as a PCB, including multiple metal layers separated from one another by layers of dielectric material and interconnected by electrically conductive vias. In some embodiments, the interposer 1204 may be formed of an epoxy resin, a fiberglass-reinforced epoxy resin, an epoxy resin with inorganic fillers, a ceramic material, or a polymer material such as polyimide. In some embodiments, the interposer 1204 may be formed of alternate rigid or flexible materials that may include the same materials described above for use in a semiconductor substrate, such as silicon, germanium, and other group III-V and group IV materials. The interposer 1204 may include metal interconnects 1208 and vias 1210, including but not limited to through hole vias 1210-1 (that extend from a first face 1250 of the interposer 1204 to a second face 1254 of the interposer 1204), blind vias 1210-2 (that extend from the first or second faces 1250 or 1254 of the interposer 1204 to an internal metal layer), and buried vias 1210-3 (that connect internal metal layers).

In some embodiments, the interposer 1204 can comprise a silicon interposer. Through silicon vias (TSV) extending through the silicon interposer can connect connections on a first face of a silicon interposer to an opposing second face of the silicon interposer. In some embodiments, an interposer 1204 comprising a silicon interposer can further comprise one or more routing layers to route connections on a first face of the interposer 1204 to an opposing second face of the interposer 1204.

The interposer 1204 may further include embedded devices 1214, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1204. The package-on-interposer structure 1236 may take the form of any of the package-on-interposer structures known in the art.

The integrated circuit device assembly 1200 may include an integrated circuit component 1224 coupled to the first face 1240 of the circuit board 1202 by coupling components 1222. The coupling components 1222 may take the form of any of the embodiments discussed above with reference to the coupling components 1216, and the integrated circuit component 1224 may take the form of any of the embodiments discussed above with reference to the integrated circuit component 1220.

The integrated circuit device assembly 1200 illustrated in FIG. 12 includes a package-on-package structure 1234 coupled to the second face 1242 of the circuit board 1202 by coupling components 1228. The package-on-package structure 1234 may include an integrated circuit component 1226 and an integrated circuit component 1232 coupled together by coupling components 1230 such that the integrated circuit component 1226 is disposed between the circuit board 1202 and the integrated circuit component 1232. The coupling components 1228 and 1230 may take the form of any of the embodiments of the coupling components 1216 discussed above, and the integrated circuit components 1226 and 1232 may take the form of any of the embodiments of the integrated circuit component 1220 discussed above. The package-on-package structure 1234 may be configured in accordance with any of the package-on-package structures known in the art.

FIG. 13 is a block diagram of an example electrical device 1300 that may include varactors as disclosed herein. For example, any suitable ones of the components of the electrical device 1300 may include one or more of the integrated circuit device assemblies 1200, integrated circuit components 1220, integrated circuit devices 1000, or integrated circuit dies 902 disclosed herein. A number of components are illustrated in FIG. 13 as included in the electrical device 1300, but any one or more of these components may be omitted or duplicated, as suitable for the application. In some embodiments, some or all of the components included in the electrical device 1300 may be attached to one or more motherboards mainboards, or system boards. In some embodiments, one or more of these components are fabricated onto a single system-on-a-chip (SoC) die.

Additionally, in various embodiments, the electrical device 1300 may not include one or more of the components illustrated in FIG. 13, but the electrical device 1300 may include interface circuitry for coupling to the one or more components. For example, the electrical device 1300 may not include a display device 1306, but may include display device interface circuitry (e.g., a connector and driver circuitry) to which a display device 1306 may be coupled. In another set of examples, the electrical device 1300 may not include an audio input device 1324 or an audio output device 1308, but may include audio input or output device interface circuitry (e.g., connectors and supporting circuitry) to which an audio input device 1324 or audio output device 1308 may be coupled.

The electrical device 1300 may include one or more processor units 1302 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1302 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1300 may include a memory 1304, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1304 may include memory that is located on the same integrated circuit die as the processor unit 1302. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1300 can comprise one or more processor units 1302 that are heterogeneous or asymmetric to another processor unit 1302 in the electrical device 1300. There can be a variety of differences between the processing units 1302 in a system in terms of a spectrum of metrics of merit including architectural, microarchitectural, thermal, power consumption characteristics, and the like. These differences can effectively manifest themselves as asymmetry and heterogeneity among the processor units 1302 in the electrical device 1300.

In some embodiments, the electrical device 1300 may include a communication component 1312 (e.g., one or more communication components). For example, the communication component 1312 can manage wireless communications for the transfer of data to and from the electrical device 1300. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1312 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1312 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1312 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1312 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1312 may operate in accordance with other wireless protocols in other embodiments. The electrical device 1300 may include an antenna 1322 to facilitate wireless communications and/or to receive other wireless communications (such as AM or FM radio transmissions).

In some embodiments, the communication component 1312 may manage wired communications, such as electrical, optical, or any other suitable communication protocols (e.g., IEEE 802.3 Ethernet standards). As noted above, the communication component 1312 may include multiple communication components. For instance, a first communication component 1312 may be dedicated to shorter-range wireless communications such as Wi-Fi or Bluetooth, and a second communication component 1312 may be dedicated to longer-range wireless communications such as global positioning system (GPS), EDGE, GPRS, CDMA, WiMAX, LTE, EV-DO, or others. In some embodiments, a first communication component 1312 may be dedicated to wireless communications, and a second communication component 1312 may be dedicated to wired communications.

The electrical device 1300 may include battery/power circuitry 1314. The battery/power circuitry 1314 may include one or more energy storage devices (e.g., batteries or capacitors) and/or circuitry for coupling components of the electrical device 1300 to an energy source separate from the electrical device 1300 (e.g., AC line power).

The electrical device 1300 may include a display device 1306 (or corresponding interface circuitry, as discussed above). The display device 1306 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1300 may include an audio output device 1308 (or corresponding interface circuitry, as discussed above). The audio output device 1308 may include any embedded or wired or wirelessly connected external device that generates an audible indicator, such speakers, headsets, or earbuds.

The electrical device 1300 may include an audio input device 1324 (or corresponding interface circuitry, as discussed above). The audio input device 1324 may include any embedded or wired or wirelessly connected device that generates a signal representative of a sound, such as microphones, microphone arrays, or digital instruments (e.g., instruments having a musical instrument digital interface (MIDI) output). The electrical device 1300 may include a Global Navigation Satellite System (GNSS) device 1318 (or corresponding interface circuitry, as discussed above), such as a Global Positioning System (GPS) device. The GNSS device 1318 may be in communication with a satellite-based system and may determine a geolocation of the electrical device 1300 based on information received from one or more GNSS satellites, as known in the art.

The electrical device 1300 may include another output device 1310 (or corresponding interface circuitry, as discussed above). Examples of the other output device 1310 may include an audio codec, a video codec, a printer, a wired or wireless transmitter for providing information to other devices, or an additional storage device.

The electrical device 1300 may include another input device 1320 (or corresponding interface circuitry, as discussed above). Examples of the other input device 1320 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1300 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1300 may be any other electronic device that processes data. In some embodiments, the electrical device 1300 may comprise multiple discrete physical components. Given the range of devices that the electrical device 1300 can be manifested as in various embodiments, in some embodiments, the electrical device 1300 can be referred to as a computing device or a computing system.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of embodiments has been described with reference to specific example embodiments, various modifications and changes may be made to these embodiments without departing from the broader scope of embodiments of the present disclosure.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

It will also be understood that, although the terms “first,” “second,” and so forth may be used herein to describe various elements, these elements should not be limited by these terms. These terms are only used to distinguish one element from another. For example, a first contact could be termed a second contact, and, similarly, a second contact could be termed a first gate and the second contact are both contacts, but they are not the same contact.

As used in the description of the example embodiments and the appended examples, the singular forms “a.” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment.” “according to some embodiments,” “in accordance with embodiments,” or “in embodiments,” which may each refer to one or more of the same or different embodiments. Furthermore, the terms “comprising,” “including.” “having.” and the like, as used with respect to embodiments of the present disclosure, are synonymous.

As used herein, the term “module” refers to being part of, or including an ASIC, an electronic circuit, a system on a chip, a processor (shared, dedicated, or group), a solid state device, a memory (shared, dedicated, or group) that execute one or more software or firmware programs, a combinational logic circuit, and/or other suitable components that provide the described functionality.

As used herein, “electrically conductive” in some examples may refer to a property of a material having an electrical conductivity greater than or equal to 107 Siemens per meter (S/m) at 20 degrees Celsius. Examples of such materials include Cu, Ag. Al, Au, W, Zn and Ni.

In the corresponding drawings of the embodiments, signals, currents, electrical biases, or magnetic or electrical polarities may be represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, polarity, current, voltage, etc., as dictated by design needs or preferences, may actually comprise one or more signals that may travel in either direction and may be implemented with any suitable type of signal scheme.

Throughout the specification, and in the claims, the term “connected” means a direct connection, such as electrical, mechanical, or magnetic connection between the elements that are connected, without any intermediary devices. The term “coupled” means a direct or indirect connection, such as a direct electrical, mechanical, or magnetic connection between the elements that are connected or an indirect connection, through one or more passive or active intermediary devices. The term “signal” may refer to at least one current signal, voltage signal, magnetic signal, or data/clock signal.

The terms “substantially.” “close.” “approximately,” “near.” and “about,” generally refer to being within +/−10% of a target value (unless specifically specified). Unless otherwise specified the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

The terms “over.” “under.” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct contact with that second material/layer. Similar distinctions are to be made in the context of component assemblies.

Unless otherwise specified in the specific context of use, the term “predominantly” means more than 50%, or more than half. For example, a composition that is predominantly a first constituent means more than half of the composition (e.g., by volume) is the first constituent (e.g., >50 at. %). The term “primarily” means the most, or greatest, part. For example, a composition that is primarily a first constituent means the composition has more of the first constituent (e.g., by volume) than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

As used throughout this description, and in the claims, a list of items joined by the term “at least one of” or “one or more of” can mean any combination of the listed terms.

Unless otherwise specified in the explicit context of their use, the terms “substantially equal,” “about equal” or “approximately equal” mean that there is no more than incidental variation between two things so described. In the art, such variation is typically no more than +/−10% of a predetermined target value.

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements.

Although the figures may illustrate embodiments where structures are substantially aligned to Cartesian axes (e.g., device structures having substantially vertical sidewalls), positive and negative (re-entrant) sloped feature sidewalls often occur in practice. For example, manufacturing non-idealities may cause one or more structural features to have sloped sidewalls. Thus, attributes illustrated are idealized merely for the sake of clearly describing salient features. It is to be understood that schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

Example 1 includes an integrated circuit device comprising a varactor comprising a first conductive contact; a second conductive contact; and a thin film transistor (TFT) channel material coupled between the first conductive contact and the second conductive contact.

Example 2 includes the subject matter of Example 1, and wherein the integrated circuit device comprises a front side comprising a plurality of transistors and interconnect layers and a back side comprising the varactor.

Example 3 includes the subject matter of any of Examples 1 and 2, and wherein the TFT channel material has a charge carrier mobility within a range of 5 cm²/(V·s) to 700 cm²/(V·s) and a bandgap voltage within a range of 1.15 eV to 6.5 eV at 300 degrees Kelvin.

Example 4 includes the subject matter of any of Examples 1-3, the varactor further comprising a non-crystalline substrate under the first conductive contact, second conductive contact, and TFT channel material.

Example 5 includes the subject matter of any of Examples 1-4, and wherein the non-crystalline substrate comprises silicon oxide, silicon nitride, a metal oxide, or silicon oxynitride.

Example 6 includes the subject matter of any of Examples 1-5, the varactor further comprising a dielectric material between the first conductive contact and the TFT channel material.

Example 7 includes the subject matter of any of Examples 1-6, and wherein the first conductive contact, second conductive contact, and TFT channel material each contact a substrate comprising a dielectric material.

Example 8 includes the subject matter of any of Examples 1-7, and wherein the first conductive contact is substantially parallel to the second conductive contact, and wherein the TFT channel material is substantially orthogonal to the first conductive contact and the second conductive contact.

Example 9 includes the subject matter of any of Examples 1-8, and wherein the TFT channel material is substantially parallel to the first conductive contact and second conductive contact in a horizontal grating configuration.

Example 10 includes the subject matter of any of Examples 1-9, and wherein the TFT channel material is between the first conductive contact and second conductive contact in a vertical stack.

Example 11 includes the subject matter of any of Examples 1-10, and wherein a depletion region is to form in the TFT channel material responsive to a voltage applied to the varactor.

Example 12 includes the subject matter of any of Examples 1-11, and wherein the varactor is an inversion mode varactor.

Example 13 includes the subject matter of any of Examples 1-12, and further including an ohmic contact material between the TFT channel material and the second conductive contact.

Example 14 includes the subject matter of any of Examples 1-13, and further including an integrated circuit die comprising the varactor.

Example 15 includes the subject matter of any of Examples 1-14, and further including a circuit board coupled to the integrated circuit die.

Example 16 includes the subject matter of any of Examples 1-15, further comprising at least one of a network interface, battery, or memory coupled to the integrated circuit die.

Example 17 includes an apparatus comprising a varactor comprising an anode; a cathode; a dielectric material in contact with the cathode; and a thin film transistor (TFT) channel material in contact with the dielectric material and coupled to the anode.

Example 18 includes the subject matter of Example 17, and wherein the integrated circuit device comprises a front side comprising a plurality of transistors and interconnect layers and a back side comprising the varactor.

Example 19 includes the subject matter of any of Examples 17 and 18, and wherein the TFT channel material has a charge carrier mobility within a range of 5 cm²/(V·s) to 700 cm²/(V·s) and a bandgap voltage within a range of 1.15 eV to 6.5 eV at 300 degrees Kelvin.

Example 20 includes the subject matter of any of Examples 17-19, the varactor further comprising a non-crystalline substrate under the anode, cathode, and TFT channel material.

Example 21 includes the subject matter of any of Examples 17-20, and wherein the non-crystalline substrate comprises silicon oxide, silicon nitride, a metal oxide, or silicon oxynitride.

Example 22 includes the subject matter of any of Examples 17-21, the varactor further comprising a dielectric material between the cathode and the TFT channel material.

Example 23 includes the subject matter of any of Examples 17-22, and wherein the anode, cathode, and TFT channel material each contact a substrate comprising a dielectric material.

Example 24 includes the subject matter of any of Examples 17-23, and wherein the anode is substantially parallel to the cathode, and wherein the TFT channel material is substantially orthogonal to the anode and the cathode.

Example 25 includes the subject matter of any of Examples 17-24, and wherein the TFT channel material is substantially parallel to the anode and cathode in a horizontal grating configuration.

Example 26 includes the subject matter of any of Examples 17-25, and wherein the TFT channel material is between the anode and cathode in a vertical stack.

Example 27 includes the subject matter of any of Examples 17-26, and wherein a depletion region is to form in the TFT channel material responsive to a voltage applied to the varactor.

Example 28 includes the subject matter of any of Examples 17-27, and wherein the varactor is an inversion mode varactor.

Example 29 includes the subject matter of any of Examples 17-28, and further including an ohmic contact material between the TFT channel material and the anode.

Example 30 includes the subject matter of any of Examples 17-29, and further including an integrated circuit die comprising the varactor.

Example 31 includes the subject matter of any of Examples 17-30, and further including a circuit board coupled to the integrated circuit die.

Example 32 includes the subject matter of any of Examples 17-31, and further including at least one of a network interface, battery, or memory coupled to the integrated circuit die.

Example 33 includes a method comprising forming a first conductive contact; forming a second conductive contact; and forming a thin film transistor (TFT) channel material over a non-crystalline substrate and between the first conductive contact and the second conductive contact.

Example 34 includes the subject matter of Example 33, and wherein the TFT channel material is deposited directly on the non-crystalline substrate.

Example 35 includes the subject matter of any of Examples 33 and 34, and further including forming a plurality of TFTs with channels comprising the TFT channel material.

Example 36 includes the subject matter of any of Examples 33-35, and further including forming a front side comprising a plurality of transistors and interconnect layers on a die and forming the varactor on a back side of the die.

Example 37 includes the subject matter of any of Examples 33-36, and wherein the TFT channel material has a charge carrier mobility within a range of 5 cm²/(V·s) to 700 cm²/(V·s) and a bandgap voltage within a range of 1.15 eV to 6.5 eV at 300 degrees Kelvin.

Example 38 includes the subject matter of any of Examples 33-37, and wherein the non-crystalline substrate is formed under the first conductive contact, second conductive contact, and TFT channel material.

Example 39 includes the subject matter of any of Examples 33-38, and wherein the non-crystalline substrate comprises silicon oxide, silicon nitride, a metal oxide, or silicon oxynitride.

Example 40 includes the subject matter of any of Examples 33-39, and further including forming a dielectric material between the first conductive contact and the TFT channel material.

Example 41 includes the subject matter of any of Examples 33-40, and wherein the first conductive contact, second conductive contact, and TFT channel material each contact a substrate comprising a dielectric material.

Example 42 includes the subject matter of any of Examples 33-41, and wherein the first conductive contact is substantially parallel to the second conductive contact, and wherein the TFT channel material is substantially orthogonal to the first conductive contact and the second conductive contact.

Example 43 includes the subject matter of any of Examples 33-42, and wherein the TFT channel material is substantially parallel to the first conductive contact and second conductive contact in a horizontal grating configuration.

Example 44 includes the subject matter of any of Examples 33-43, and wherein the TFT channel material is between the first conductive contact and second conductive contact in a vertical stack.

Example 45 includes the subject matter of any of Examples 33-44, and wherein a depletion region is to form in the TFT channel material responsive to a voltage applied to the varactor.

Example 46 includes the subject matter of any of Examples 33-45, and wherein the varactor is an inversion mode varactor.

Example 47 includes the subject matter of any of Examples 33-46, and further including an ohmic contact material between the TFT channel material and the second conductive contact.

Example 48 includes the subject matter of any of Examples 33-47, and further including forming an integrated circuit die comprising the varactor.

Example 49 includes the subject matter of any of Examples 33-48, and further including forming a circuit board coupled to the integrated circuit die.

Example 50 includes the subject matter of any of Examples 33-49, and further including coupling at least one of a network interface, battery, or memory to the integrated circuit die.

1. An integrated circuit device comprising:
a varactor comprising:
a first conductive contact;
a second conductive contact; and
a thin film transistor (TFT) channel material coupled between the first conductive contact and the second conductive contact.

2. The integrated circuit device of claim 1, wherein the integrated circuit device comprises a front side comprising a plurality of transistors and interconnect layers and a back side comprising the varactor.

3. The integrated circuit device of claim 1, wherein the TFT channel material has a charge carrier mobility within a range of 50 cm²/(V·s) to 700 cm²/(V·s) and a bandgap voltage within a range of 1.15 eV to 6.5 eV at 300 degrees Kelvin.

4. The integrated circuit device of claim 1, the varactor further comprising a non-crystalline substrate under the first conductive contact, second conductive contact, and TFT channel material.

5. The integrated circuit device of claim 4, wherein the non-crystalline substrate comprises silicon oxide, silicon nitride, a metal oxide, or silicon oxynitride.

6. The integrated circuit device of claim 1, the varactor further comprising a dielectric material between the first conductive contact and the TFT channel material.

7. The integrated circuit device of claim 1, wherein the first conductive contact, second conductive contact, and TFT channel material each contact a substrate comprising a dielectric material.

8. The integrated circuit device of claim 7, wherein the first conductive contact is substantially parallel to the second conductive contact, and wherein the TFT channel material is substantially orthogonal to the first conductive contact and the second conductive contact.

9. The integrated circuit device of claim 7, wherein the TFT channel material is substantially parallel to the first conductive contact and second conductive contact in a horizontal grating configuration.

10. The integrated circuit device of claim 1, wherein the TFT channel material is between the first conductive contact and second conductive contact in a vertical stack.

11. The integrated circuit device of claim 1, wherein a depletion region is to form in the TFT channel material responsive to a voltage applied to the varactor.

12. The integrated circuit device of claim 1, wherein the varactor is an inversion mode varactor.

13. An apparatus comprising:
a varactor comprising:
an anode;
a cathode;
a dielectric material in contact with the cathode; and
a thin film transistor (TFT) channel material in contact with the dielectric material and coupled to the anode.

14. The apparatus of claim 13, further comprising an ohmic contact material between the TFT channel material and the anode.

15. The apparatus of claim 13, further comprising an integrated circuit die comprising the varactor.

16. The apparatus of claim 15, further comprising a circuit board coupled to the integrated circuit die.

17. The apparatus of claim 16, further comprising at least one of a network interface, battery, or memory coupled to the integrated circuit die.

18. A method of forming a varactor, the method comprising:
forming a first conductive contact;
forming a second conductive contact; and
forming a thin film transistor (TFT) channel material over a non-crystalline substrate and between the first conductive contact and the second conductive contact.

19. The method of claim 18, wherein the TFT channel material is deposited directly on the non-crystalline substrate.

20. The method of claim 18, further comprising forming a plurality of TFTs with channels comprising the TFT channel material.
